(19) United States
(12) Patent Application Publication
(10) Pub. No.: US 2014/0085790 A1
(43) Pub. Date: Mar. 27, 2014

(54) SERVER RACK

(71) Applicant: HON HAI PRECISION INDUSTRY CO., LTD., New Taipei (TW)

(72) Inventors: CHEN-LU FAN, New Taipei (TW); LI-PING CHEN, New Taipei (TW)

(21) Appl. No.: 13/913,457

(22) Filed: Jun. 9, 2013

(30) Foreign Application Priority Data
Sep. 21, 2012 (TW) 101134853

(51) Int. Cl. H05K 7/14

(52) U.S. Cl. CPC H05K 7/1489
USPC 361/679.02

(57) ABSTRACT

A server rack includes a server rack main body, a mounting bracket, and a power socket secured to the mounting bracket. The server rack main body includes a frame and a pole connected to the frame. The pole includes a first inner wall and a second inner wall connected to the first inner wall. The first inner wall defines a first clipping hole. The mounting bracket includes a bottom panel with a first hook. The mounting bracket is moveable in a direction substantially perpendicular to a plane that the frame is positioned, so that the first hook is engaged in the first clipping hole.

### BACKGROUND

1. Technical Field

The present disclosure relates to electronic device enclosure, more particularly to a server rack.

2. Description of Related Art

Blade and rack-mounted servers are popular form factors for data center servers. In order to achieve high performance, many rack-mounted servers are clustered in an enclosure. Usually, a server rack includes a power socket received in the enclosure. In assembly, the power socket is secured to a mounting bracket with a plurality of first screws. The mounting bracket is secured to the enclosure with a plurality of second screws, which is time-consuming and laborious. Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, cutaway view of a server rack in accordance with an embodiment.

FIG. 2 is an enlarged view of a circled portion II of FIG. 1.

FIG. 3 is similar to FIG. 1, but viewed from a different aspect.

FIG. 4 is an isometric view of a mounting bracket of FIG. 1.

FIG. 5 is an assembled view of the server rack of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one”.

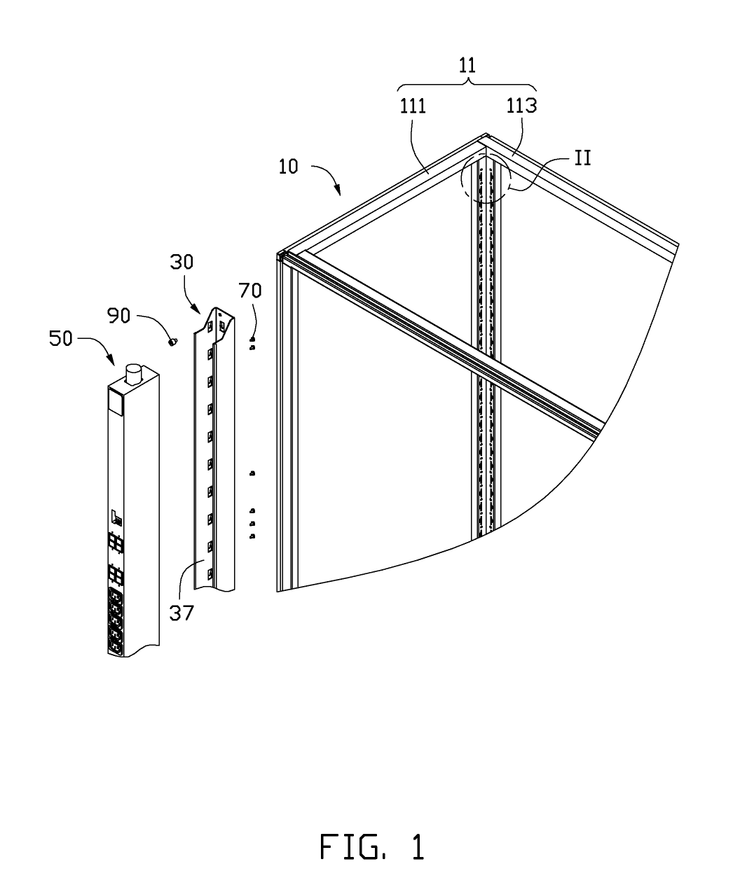

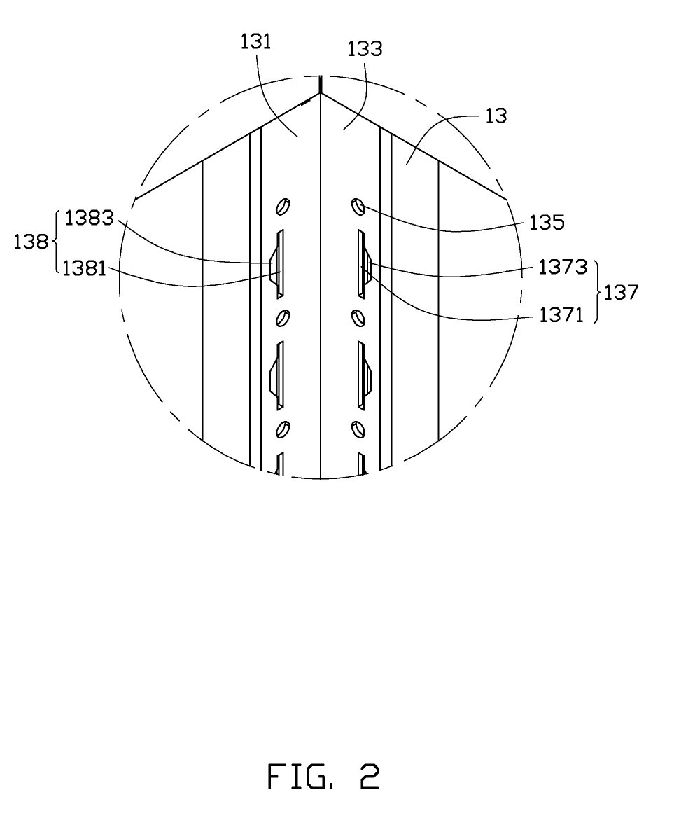

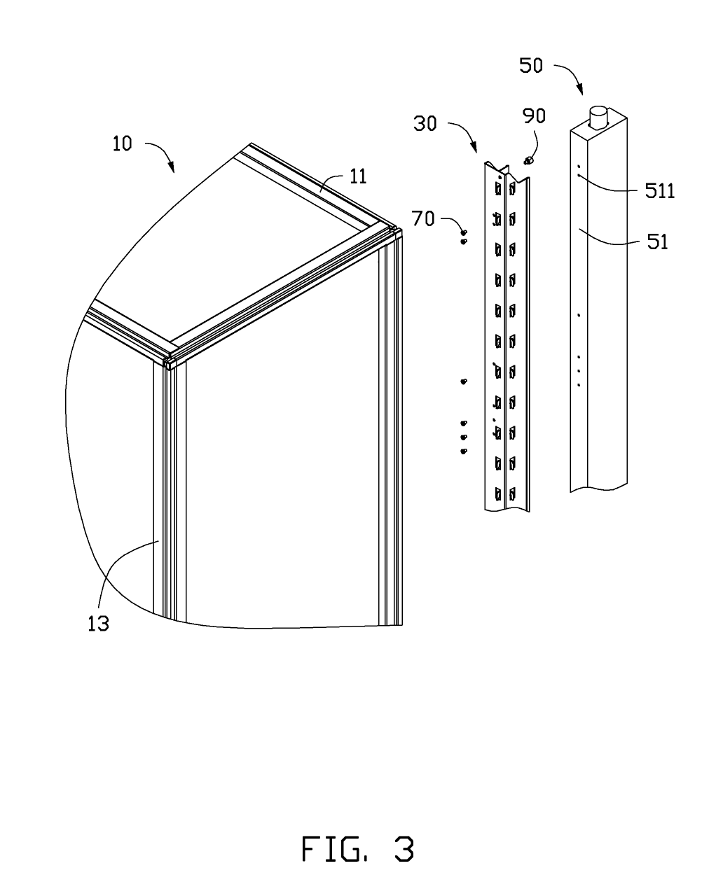

FIGS. 1-3 illustrate a server rack in accordance with an embodiment. The server rack comprises a server rack main body 10, a mounting bracket 30 attached to the server rack main body 10, and a power socket 50 attached to the mounting bracket 30.

The server rack main body 10 comprises a frame 11 and a plurality of poles 13 connected to the frame 11. In one embodiment, the frame 11 is substantially rectangular. The frame 11 comprises two first parallel frame posts 111 and two second parallel frame posts 113. Each of the two first frame posts 111 is substantially perpendicular to each of the two second frame posts 113. Each of the plurality of poles 13 is substantially parallel to each other and substantially perpendicular to a plane that the frame 11 is positioned. Each of the plurality of poles 13 comprises a first inner wall 133 and a second inner wall 131 substantially perpendicular to the first inner wall 133. In one embodiment, the first inner wall 133 is substantially parallel to the first frame post 111, and the second inner wall 131 is substantially parallel to the second frame post 113. A plurality of mounting holes 135 and a plurality of first clipping holes 137 are defined in the first inner wall 133. Each of the plurality of first clipping holes 137 comprises a first clipping portion 1371 and a first guiding portion 1373 communicating with the first clipping portion 1371. A plurality of second clipping holes 138 are defined in the second inner wall 131. Each of the plurality of second clipping holes 138 comprises a first clipping portion 1381 and a first guiding portion 1383 communicating with the first clipping portion 1381. In one embodiment, the plurality of mounting holes 135 and the plurality of first clipping holes 137 are arranged at a straight line, the first and second clipping portions 1371, 1381 are substantially a rectangular, and the first and second guiding portion 1373, 1373 are substantially a trapezoid.

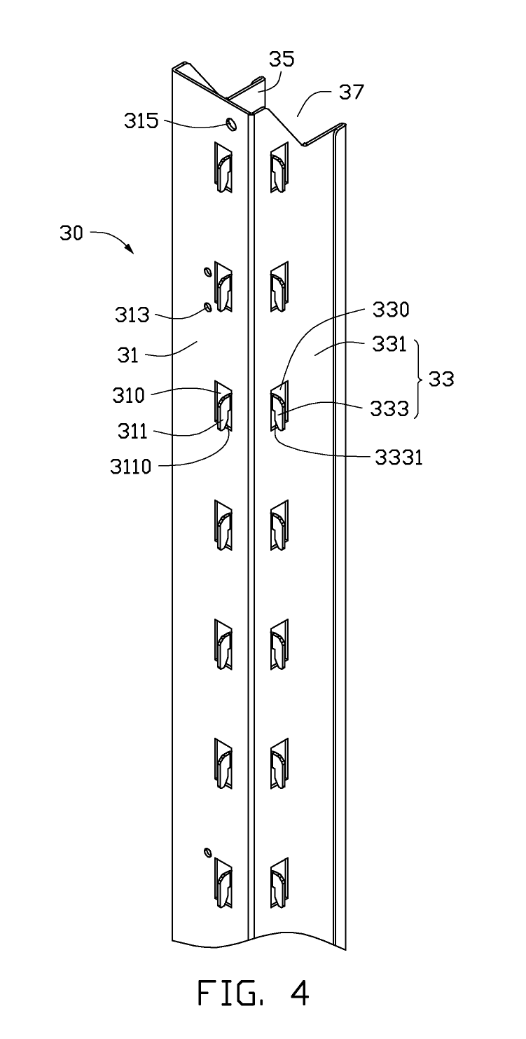

FIG. 4 shows that the mounting bracket 30 comprises a bottom panel 31, a first side panel 33, and a second side panel 35 substantially parallel to the first side panel 33. The first side panel 33 and the second side panel 35 extend from opposite edges of the bottom panel 31. The bottom panel 31, the first side panel 33 and the second side panel 35 cooperatively define a receiving space 37. The bottom panel 31 defines a plurality of first openings 310, a plurality of securing holes 313, and a through hole 315. A first hook 311 extends from an edge of each of the plurality of first openings 310. The first hook 311 comprises a first guiding surface 3110 towards the bottom panel 31. The first side panel 33 defines a plurality of second openings 330. A second hook 333 extends from an edge of each of the plurality of second openings 330. The second hook 333 comprises a second guiding surface 3331 towards the first side panel 33. In one embodiment, the first hook 311 and the second hook 333 are substantially L-shaped, and the first guiding surface 3110 and the second guiding surface 3331 are arcuate.

The power socket 50 comprises a bottom plate 51 substantially parallel to the bottom panel 31. A plurality of fixing holes 511 are defined in the bottom plate 51.

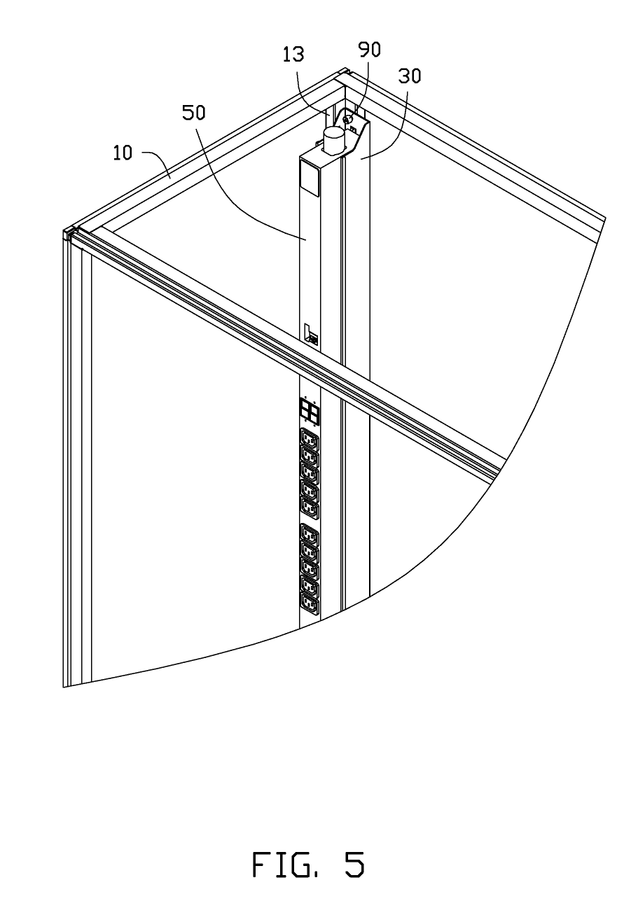

FIGS. 1 and 5, show that in assembly, the power socket 50 is received in the receiving space 37, and the plurality of fixing holes 511 are aligned with the plurality of securing holes 313. A plurality of first mounting members 70 are engaged in the plurality of fixing holes 511, so that the power socket 50 is secured to the mounting bracket 30. The first hooks 311 are aligned with the plurality of first clipping holes 137, and the second hooks 333 are aligned with the plurality of second clipping holes 138. The first hooks 311 extend through the plurality of first clipping holes 137, the second hooks 333 extend through the plurality of second clipping holes 138, and the power socket 50 is moved downwards to clip the first and second hooks 311, 333 into the plurality of first and second clipping holes 137, 138. At this point, the through hole 315 is aligned with the one of the plurality of mounting holes 135. A second mounting member 90 is engaged in the through hole 315 and the one of the plurality of mounting holes 135, so that the mounting bracket 30 is secured to the pole 13.

In disassembly, the second mounting member 90 is detached from the through hole 315 and the one of the plurality of mounting holes 135. The power socket 50 is moved upwards, and the first and second guiding surfaces 3110, 3331 are slid along the edges of the first and second clipping holes 137, 138, until the first and second hooks 311, 333 disengage from the plurality of first and second clipping holes 137, 138. Thus, the power socket 50 with the mounting bracket 30 can be removed from the pole 13.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A server rack comprising:
a server rack main body comprising a frame and a pole that is substantially perpendicular to a plane defined by the frame; the pole comprises a first inner wall and a second inner wall connected to the first inner wall; and the first inner wall defining a first clipping hole;
a mounting bracket comprising a bottom panel attached to the first inner wall, a first side panel attached to the second inner wall, and a second side panel that is substantially parallel to the first side panel; a first hook extending from the bottom panel; and a receiving space defined by the bottom panel, the first side panel, and the second side panel; and
a power socket, received in the receiving space, attached to the bottom panel;
wherein the mounting bracket is moveable in a direction substantially perpendicular to the plane, and the first hook is engaged in the first clipping hole.

2. The server rack of claim 1, wherein the first inner wall is substantially perpendicular to the second inner wall.

3. The server rack of claim 1, wherein the bottom panel is substantially perpendicular to the first side panel.

4. The server rack of claim 1, wherein the bottom panel defines a first opening, and the first hook extends from an edge of the first opening.

5. The server rack of claim 1, wherein the first hook comprises a first guiding surface towards the bottom panel, and the first guiding surface is arcuate.

6. The server rack of claim 1, wherein the bottom panel defines a securing hole, and the first inner wall defines a mounting hole; and a first mounting member is engaged in the securing hole and the mounting hole, to secure the bottom panel to the first inner wall.

7. The server rack of claim 6, wherein the securing hole and the first clipping hole are arranged at a straight line.

8. The server rack of claim 1, wherein the second inner wall defines a second clipping hole, and the first side panel comprises a second hook clipped in the second clipping hole.

9. The server rack of claim 1, wherein the first clipping holes comprises a first clipping portion and a first guiding portion communicating with the first clipping portion, the first clipping portion is substantially a rectangular, and the first guiding portion is substantially a trapezoid.

10. A server rack comprising:
a server rack main body comprising a frame and a pole that is substantially perpendicular to a plane defined by the frame; the pole comprises a first inner wall and a second inner wall connected to the first inner wall; and the first inner wall defining a first clipping hole, and
a mounting bracket comprising a bottom panel attached to the first inner wall and a first side panel attached to the second inner wall; the bottom panel comprising a first hook; and
a power socket attached to the bottom panel;
wherein the mounting bracket is moveable in a direction that is substantially perpendicular to the plane, and the first hook is engaged in the first clipping hole.

11. The server rack of claim 10, wherein the first inner wall is substantially perpendicular to the second inner wall.

12. The server rack of claim 11, wherein the mounting bracket comprises a second side panel substantially parallel to the first side panel; the bottom panel, the first side panel and the second side panel cooperatively defines a receiving space, and the power socket is received in the receiving space.

13. The server rack of claim 12, wherein the bottom panel is substantially perpendicular to the first side panel.

14. The server rack of claim 10, wherein the bottom panel defines a first opening, and the first hook extends from an edge of the first opening.

15. The server rack of claim 14, wherein the first hook comprises a first guiding surface towards the bottom panel, and the first guiding surface is arcuate.

16. The server rack of claim 10, wherein the bottom panel defines a securing hole, the first inner wall defines a mounting hole; and a first mounting member is engaged in the securing hole and the mounting hole, to secure the bottom panel to the first inner wall.

17. The server rack of claim 16, wherein the securing hole and the first clipping hole are arranged at a straight line.

18. The server rack of claim 10, wherein the second inner wall defines a second clipping hole, and the first side panel comprises a second hook clipped in the second clipping hole.

19. The server rack of claim 10, wherein the first clipping holes comprises a first clipping portion and a first guiding portion communicating with the first clipping portion, the first clipping portion is substantially a rectangular, and the first guiding portion is substantially a trapezoid.
